(19) United States
(12) Patent Application Publication
(10) Pub. No.: US 2023/0020411 A1
(43) Pub. Date: Jan. 19, 2023

(54) MITIGATING FAN NOISE IN HDD STORAGE SYSTEM

(71) Applicant: Microsoft Technology Licensing, LLC, Redmond, WA (US)

(72) Inventors: Jason David ADRIAN, Woodinville, WA (US); Dominic Kai Yin CHENG, Bellevue, WA (US); Nicholas Andrew KEEHN, Kirkland, WA (US)

(73) Assignee: Microsoft Technology Licensing, LLC, Redmond, WA (US)

(21) Appl. No.: 17/377,265

(22) Filed: Jul. 15, 2021

(51) Int. Cl. G06F 1/20; H05K 7/20; G10K 11/162

(52) U.S. Cl. CPC G06F 1/20; H05K 7/20136; G10K 11/162

(57) ABSTRACT

Examples are disclosed that relate to attenuating fan noise in a computing storage system comprising magnetic data storage devices. One example provides a computing storage system comprising an enclosure, a plurality of magnetic data storage devices positioned within the enclosure, one or more fans positioned to cool the magnetic data storage devices, and an acoustic attenuator located between the plurality of magnetic data storage devices and the one or more fans. The acoustic attenuator comprises a plurality of airflow channels each defined by one or more internal walls of the acoustic attenuator, wherein at least one of the plurality of airflow channels is configured to block a line of sight between the plurality of magnetic data storage devices and the one or more fans.

### BACKGROUND

Various computing systems, such as cloud computing systems, may include data storage systems comprising a plurality of magnetic data storage devices (e.g. hard disk drives (HDDs)) housed within an enclosure. Such a data storage system also may include one or more fans configured to cool the magnetic data storage devices.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to attenuating fan noise in a computing storage system comprising magnetic data storage devices. One example provides a computing storage system comprising an enclosure, a plurality of magnetic data storage devices positioned within the enclosure, one or more fans positioned to cool the magnetic data storage devices, and an acoustic attenuator located between the plurality of magnetic data storage devices and the one or more fans. The acoustic attenuator comprises a plurality of airflow channels each defined by one or more internal walls of the acoustic attenuator, wherein at least one of the plurality of airflow channels comprises a directional change that blocks a line of sight between the plurality of magnetic data storage devices and the one or more fans.

### BRIEF DESCRIPTION OF THE DRAWINGS

FIG. 1 shows a block diagram depicting an example magnetic data storage system in the form of an HDD storage system.

FIG. 2 shows an example acoustic attenuator.

FIG. 3 shows a cutaway view of the example acoustic attenuator of FIG. 2.

FIG. 4 shows a schematic view of another example acoustic attenuator.

FIG. 5 shows a schematic view of another example acoustic attenuator.

FIG. 6 shows an example acoustic attenuator comprising an array of through-holes.

FIG. 7 shows an example configuration of through-holes for the acoustic attenuator of FIG. 6.

FIG. 8 schematically shows another example acoustic attenuator comprising through-holes, and illustrates an example spiral-shaped interior wall.

FIG. 9 shows an example acoustic attenuator comprising through-holes and an absorbing chamber.

### DETAILED DESCRIPTION

As mentioned above, a computing system, such as a network-accessible cloud computing system, may comprise storage systems having a plurality of hard disk drives (HDDs) or other magnetic data storage devices (e.g. magnetic tape devices) arranged in an enclosure that also comprises one or more cooling fans. As computing hardware continues to scale to smaller and smaller feature sizes, high-capacity magnetic data storage devices, such as HDDs having capacities of 10 TB or larger, are increasingly used. Such high-capacity magnetic data storage devices may perform reads and writes on magnetic particles that are on the order of nanometers in size. With such fine feature sizes, a drive head used to perform read and write operations may be suspectable to vibrations, including vibrations from acoustic noise in the storage system. Such high-capacity drives may be particularly susceptible to vibrations within a frequency range of 4 kHz to 9 kHz. The upper end of this range may further increase as tracks per inch of hard disk drives increases.

One potential source of acoustical noise in a magnetic data storage system is cooling fans in an enclosure for the magnetic storage devices of the storage system. Mechanical motion of the cooling fan blades, airflow over mechanical features, etc. can lead to acoustic noise. In view of the fine dimensions of magnetic particles, noise from the fans can potentially impact read and write performance. To mitigate such issues, an enclosure for a magnetic data storage system may comprise an acoustic attenuator located between the fans and the magnetic data storage devices, wherein the acoustic attenuator is configured to attenuate fan noise that is directed toward the magnetic data storage devices. However, current acoustic attenuators may pose various problems. For example, some attenuators comprise an array of attenuating elements separated by slots, wherein each attenuating element comprises a sound-absorbing material arranged inside of a container that is open on the sides that define the slots. The attenuating elements are arranged across a width of an interior of the enclosure. Sound waves that enter the slots in a direction transverse to a length of the slot may pass into an interior of an attenuating element adjacent to the slot, and thereby be attenuated. However, the slots provide a line of sight between the fans and magnetic data storage devices. Thus, sound waves that enter a slot in the direction parallel to the length of the slot can pass through unattenuated, and possibly impact read and/or write performance of the magnetic data storage devices. Further, the area of the openings of the slots may be relatively small compared to the surface area of the array of attenuating elements. Thus, the array of attenuating elements may increase an impedance of the airflow from the magnetic data storage devices to the one or more fans, while still providing a direct line of sight between one or more fans and the magnetic data storage devices. Running fans at higher power may compensate for the increased impedance. However, such fan operation may cause more fan noise than lower power fans and also have a higher cost.

Accordingly, examples are disclosed that relate to acoustic attenuators configured to attenuate fan noise in a magnetic data storage system. As described in more detail below, an acoustic attenuator according to the present disclosure includes a plurality of airflow channels contained within a body of the acoustic attenuator. One or more of the airflow channels comprises a directional change configured to block a line of sight between one or more fans and magnetic data storage devices, thereby preventing noise from the one or more fans from passing through the airflow channel without impinging a surface within the acoustic attenuator. The airflow channels also provide relatively lower impedance compared to attenuator designs that comprise an array of attenuating elements separated by slots, and yet do not provide a line of sight between one or more fans and the magnetic data storage devices in the storage system.

Each airflow channel of an acoustic attenuator according to the present disclosure is defined by one or more internal walls. In some examples, an internal wall of each of one or more airflow channels comprises one or more of a curvature or an angled direction change that blocks the line of sight between the one or more fans and the hard disk drives. In other examples, an acoustic attenuator comprises airflow channels in the form of an array of through-holes extending through a body of the acoustic attenuator, wherein the airflow channels comprise a curved interior wall configured to block a line of sight between one or more fans and magnetic data storage devices. These examples are described in more detail below. While described below in the context of example HDD storage systems, it will be understood that the disclosed examples may apply to any other suitable magnetic data storage system.

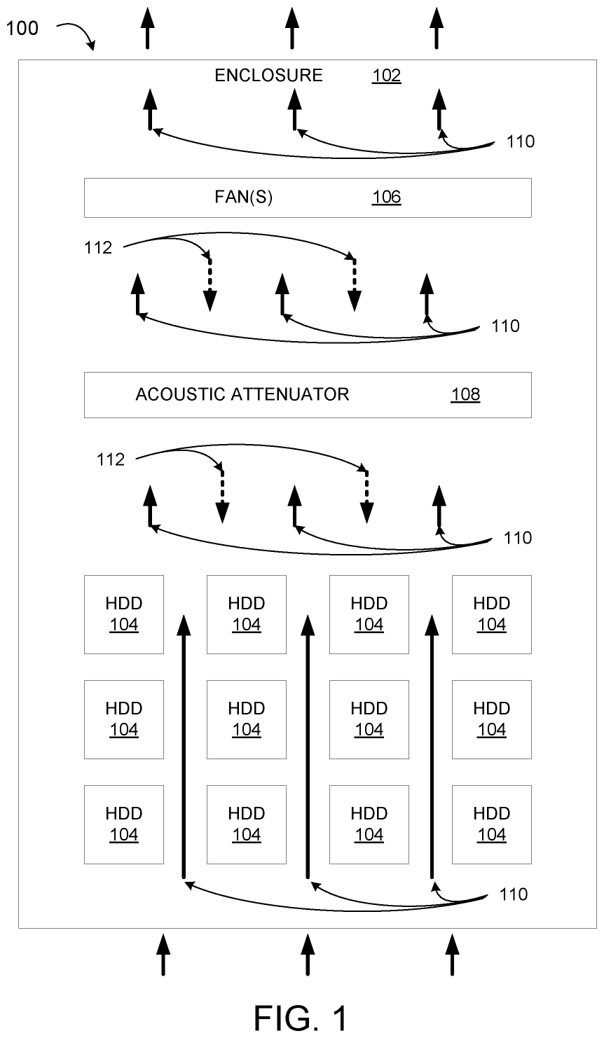

FIG. 1 shows a block diagram illustrating an example computing storage system 100. Computing storage system 100 may be deployed in a cloud computing system or other suitable data storage environment. The term “cloud computing system” represents a system configured to provide a range of computing services, including compute power and data storage delivered on-demand via the internet. Computing storage system 100 comprises an enclosure 102, a plurality of hard disk drives (HDDs) 104, one or more fans 106, and an acoustic attenuator 108 located between fan(s) 106 and HDDs 104. Fan(s) 106 are positioned to move air to cool HDDs 104, shown as airflow 110. In this example, fans(s) 106 pull air across the HDDs and then through acoustic attenuator 108. In other examples, fan(s) 106 may push air through acoustic attenuator 108 and then through HDDs 104. Further, acoustic attenuator 108 also may provide some structural rigidity to enclosure 102 by coupling sides of enclosure 102 together.

Acoustic attenuator 108 comprises a plurality of airflow channels. Each of the plurality of airflow channels is defined by one or more internal walls contained within a body of acoustic attenuator 108, wherein the one or more internal walls comprise a directional change configured to block a line of sight between fans 106 and HDDs 104. Configuring internal walls to block lines of sight between fan(s) 106 and HDDs 104 causes acoustic signals 112 traveling in any direction through acoustic attenuator 108 to impinge one or more of the internal walls, thereby attenuating acoustic signals 112. In some examples, the internal walls are configured such that no lines of sight extend through acoustic attenuator 108 between fans(s) 106 and HDDs 104. Example configurations of internal walls are described in more detail below.

In addition to blocking lines of sight between fan(s) 106 and HDDs 104, the airflow channels of an acoustic attenuator according to the disclosed examples also are configured to have a lower impedance than current attenuators comprising arrays of attenuating elements separated by slots. The lower impedance may allow the use of lower power, and thus quieter, fan(s) 106.

Further, in some examples, interior surfaces of acoustic attenuator 108 may be made at least partially from a material that absorbs at least a portion of incident sound waves. For example, one or more internal walls of acoustic attenuator 108 may be molded or otherwise formed from an acoustically attenuating material, while in other examples, one or more internal walls may be coated with such a material. Examples of acoustically attenuating materials include various solid polymer materials (e.g. an elastomeric and/or thermoplastic material), foamed polymer materials (e.g. an open cell foam or a closed cell foam), ceramic materials (e.g. a porous ceramic), composite materials comprising a curable polymer resin and a reinforcing fiber, and cellulosic materials (e.g. bamboo or other suitable wood). Further, in some examples, one or more internal walls of acoustic attenuator 108 alternatively or additionally may comprise a surface that has been treated to have a texture that helps attenuate incident sound saves. For example, one or more internal walls may be formed from a material with a roughened surface configured to diffusely reflect incident sound waves.

In some examples, an acoustic attenuator may comprise materials configured to attenuate acoustic signals across a broad range of frequencies. In other examples, an acoustic attenuator may comprise materials configured to attenuate acoustic signals within a frequency of interest (e.g. within in a range of 4 kHz to 9 kHz or higher.)

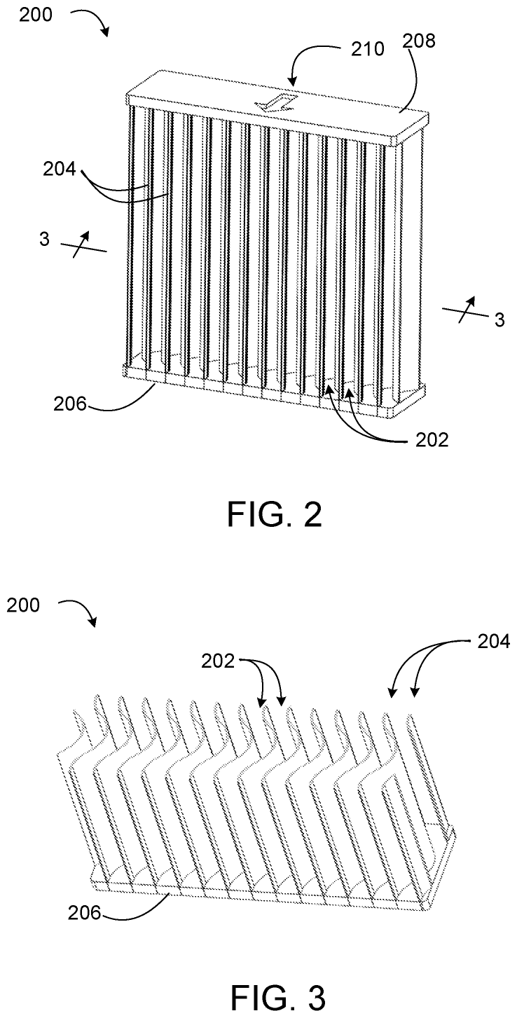

As mentioned above, an airflow channel of an acoustic attenuator according to the present disclosure comprises a directional change that blocks a line of sight between a fan and HDDs of an HDD storage system. FIG. 2 shows a view of a portion of an example acoustic attenuator 200, and FIG. 3 shows a cutaway view of acoustic attenuator 200 taken along line 3-3 of FIG. 2. Acoustic attenuator 200 is an example of acoustic attenuator 108. Acoustic attenuator 200 comprises a plurality of airflow channels 202 each defined by internal walls 204 extending across an internal dimension of acoustic attenuator 200 between a first outer wall 206 and a second outer wall 208 of a body of acoustic attenuator 200, wherein the term “body” indicates solid portions of acoustic attenuator 200 that surround airflow channels 202. An arrow indicates airflow direction 210 through acoustic attenuator 200. In the depicted example, internal walls 204 extend across a thickness dimension of acoustic attenuator 200 (vertically oriented in FIG. 2), while in other examples internal walls can extend across a width dimension (side to side in FIG. 2), or along a direction diagonal relative to the width and thickness dimensions of acoustic attenuator 200. The term “thickness dimension” as used herein indicates a smaller dimension transverse to airflow direction 210 through the airflow channel, and the term “width dimension” indicates a larger dimension transverse to the airflow direction. In the view of FIG. 2, only a portion of a width dimension of acoustic attenuator 200 is shown for clarity, as the width dimension may be substantially larger than the thickness dimension to extend across an interior width of an enclosure of an HDD storage system.

In acoustic attenuator 200, each internal wall 204 comprises a curvature that blocks a line of sight between a first end of one airflow channel 202 and a second end of the same airflow channel 202. Any suitable curvature may be used. Referring to FIG. 3, the internal walls of the depicted embodiment have a wave-like shape along a length of each airflow channel, wherein a magnitude of curvature extends just far enough to block a line of sight through acoustic attenuator 200 in airflow direction 210. In such an example, the curvature causes airflow in any direction to encounter an internal surface of acoustic attenuator 200, while not increasing airflow impedance unnecessarily.

The degree of curvature chosen for an internal wall 204 may be a function of a pitch of the internal walls 204 (i.e. a distance between internal walls 204), among other potential factors. The use of a greater distance between internal walls may provide for a somewhat greater ratio of open area to total area of an entrance side of an acoustic attenuator, but also may involve the use of a greater magnitude of inner wall curvature to block lines of sight between the one or more fans and HDDs of an HDD storage system. Likewise, the use of a lesser distance between internal walls may provide for a somewhat lesser ratio of open area to total area of an entrance side of an acoustic attenuator, but may allow the use of a lesser magnitude of inner wall curvature to block lines of sight. The use of a greater number of internal walls, and thus a lesser distance between internal walls, may help to provide for a greater amount of structural support than the use of a greater distance between internal walls, and thus may help to reinforce an HDD enclosure against bending while the HDD storage unit is mounted in a rack. It will be appreciated that a number of and degree of curvature of internal walls utilized may be selected to balance such factors as airflow impedance, fan noise attenuation and structural support.

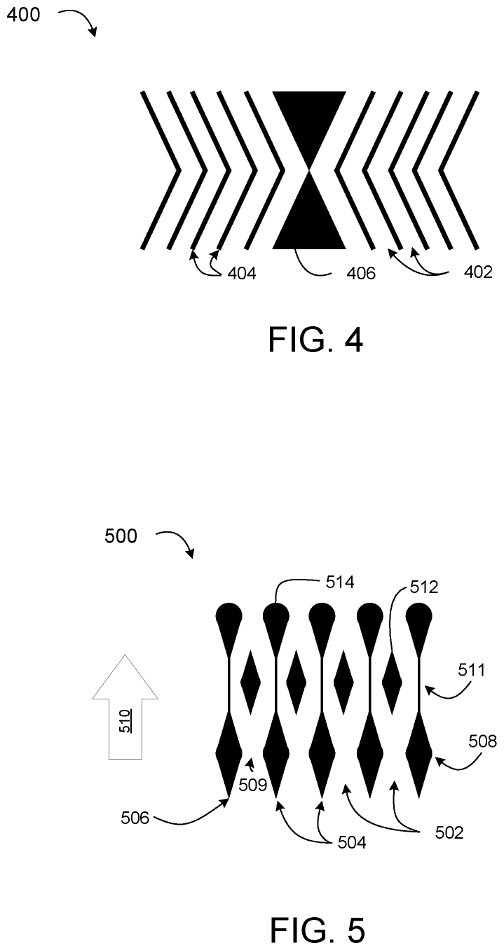

FIG. 4 shows a schematic view of internal walls of another example acoustic attenuator 400. Acoustic attenuator 400 is another example of acoustic attenuator 108. Body structures other than internal walls are omitted from this schematic figure. Acoustic attenuator 400 comprises a plurality of airflow channels 402 each defined by one or more internal walls 404. In this example, each internal wall 404 comprises an angular directional change of sufficient magnitude to block a line of sight through the airflow channels of the acoustic attenuator. In the depicted example, each internal wall 404 comprises a single angled direction change. The use of a low number of angular directional changes may help to provide for a lower internal impedance than the use of a greater number of angular directional changes. Nevertheless, in other examples, any other suitable number of angled direction changes may be used. The angular directional change may have any suitable magnitude. In some examples, the magnitude of an angular directional change of an internal wall may be sufficient to just block a line of sight through an airflow channel, while in other examples, the magnitude may be greater. As described above, the magnitude of an angular directional change may depend upon such factors as a pitch of the internal walls and a degree of structural reinforcement to be provided by the internal walls.

In the depicted example, acoustic attenuator 400 comprises a relatively thicker internal wall 406. Thicker internal wall 406 may be configured to provide additional structural support compared to internal walls 404. As internal walls 404 may be made from a relatively soft material (e.g. a thermoplastic polymer, elastomer, or open or closed cell foam), the use of one or more thicker internal walls 406 with suitable spacing may help to provide for additional structural support, thereby providing rigidity and helping acoustic attenuator 400 to hold its shape. Further, the use of one or more thicker walls 406 also may help to structurally reinforce an HDD storage system that incorporates acoustic attenuator 400. In the depicted example, thicker internal wall 406 defines an inversion in the direction of the angled directional change of the airflow channels on either side of the thicker inner wall 406. In other examples, a thicker internal wall may not define such an inversion, such that internal walls on either side of a relatively thicker internal wall have a same directional change. In the depicted example, thicker internal wall 406 comprises triangular sections arranged point to point. In other examples, a thicker internal wall may have any other suitable shape. While FIGS. 2-3 depict an acoustic attenuator 200 having curved interior walls and FIG. 4 depicts an acoustic attenuator 400 comprising angular interior walls, other examples may comprise a combination of curved and angular interior walls.

FIG. 5 shows a schematic view of internal walls of another example acoustic attenuator 500. Acoustic attenuator 500 is another example of acoustic attenuator 108, and comprises a plurality of airflow channels 502 each defined by internal walls. In the example of FIG. 5, two different configurations of internal walls are shown. A first internal wall 504 varies in width along a length in a direction of airflow 510. More particularly, first internal wall 504 comprises a leading edge 506 having a relatively sharp configuration. This transitions into a wider section 508 that, in combination with adjacent first internal walls 504, forms narrowed channels 509 within airflow channel 502. Such a configuration may help to form a plenum between HDDs and the acoustic attenuator 500. Further, wider sections 508 of first internal walls 504 may provide additional structural support against bending for an enclosure of an HDD storage system. Continuing, first internal wall 504 narrows again toward an intermediate narrower portion 511 to form a relatively wider section of airflow channel 502, in which a second internal wall 512 having a lesser length than first internal wall 504 is positioned. Second internal wall 512 and wider section 508 of first internal wall 504 together block lines of sight through airflow channels 502. Further, second internal wall 512 can provide additional structural support for an enclosure of an HDD storage system.

First internal wall 504 further comprises a curved trailing end 514 (e.g. elliptically shaped, teardrop-shaped or other suitable curved shape). Curved trailing end 514 may help reduce turbulence of airflow 510 as it exits from airflow channels 502. As discussed with regard to FIG. 1, airflow through acoustic attenuator 500 may travel towards one or more fans in an enclosure of a computing storage system. Turbulence added to airflow 510 may increase airflow impedance and may impact a performance of the fans. Further, a sharp trailing edge may create relatively higher frequency acoustic noise as air flows across the trailing edge, which may impact HDD performance. Thus, the use of a curved trailing end 514 For internal wall 504 may help to reduce impedance through an airflow channel, and further may help to avoid the production of higher frequency acoustic noise that may impact HDD operation.

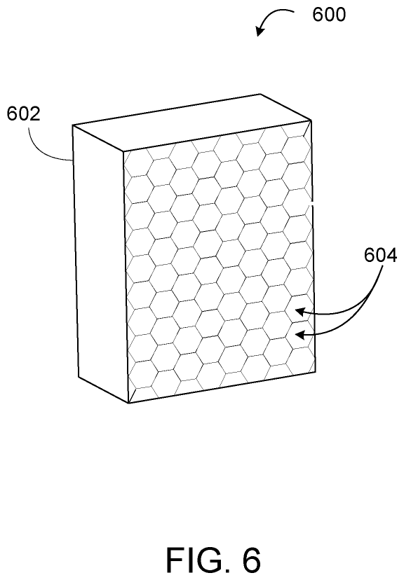

In the example acoustic attenuators of FIGS. 2-5, the internal walls extend between opposing sides of a body of each example acoustic attenuator. As such, the resulting airflow channels also extend between the opposing internal sides. FIG. 6 shows an example acoustic attenuator 600 in which the airflow channels comprise an array of through-holes 604 formed through a body 602 of acoustic attenuator 600. Acoustic attenuator 600 is an example of acoustic attenuator 108. At least one through-hole 604 is configured to block a line of sight between a first end of through-hole 604 and a second end of the through-hole 604, such as by having a curved path. In some examples, each through-hole is configured to block lines of sight, such that the acoustic attenuator comprises no direct lines of sight through the through-holes. With such a configuration, all portions of an acoustic signal traveling through the array of through-holes 604 may strike one or more surfaces of through-hole 604, thereby attenuating the acoustic signal. Further, as discussed above, the walls of the through-holes may be coated with an acoustically attenuating material, and/or treated to form an acoustically attenuating surface texture, which may help to increase a magnitude of the attenuation experienced by sound waves with each impingement on an interior wall of acoustic attenuator 600 compared to an uncoated and/or untreated surface.

Through-holes 604 may have any suitable configuration. In the depicted example, each through-hole 604 comprises a hexagonal cross section. Such a configuration may help to reduce space between through-holes compared to other shapes, such as elliptical cross-sections. This may help to provide for lower impedance. In other examples, any other suitable cross-sectional shape may be used, including other polygonal cross-sectional shapes (e.g. square or triangle), elliptical shapes, other curved shapes, and shapes comprising various combinations of polygonal and curved perimeter segments.

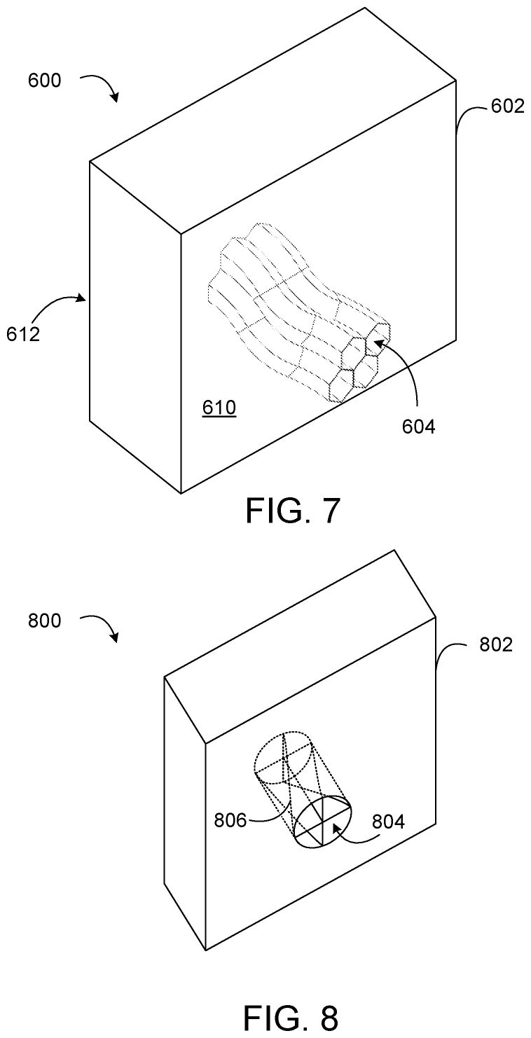

Each through-hole 604 may comprise any suitable configuration that blocks a line of sight through the through-hole. FIG. 7 shows an example configuration for through-holes 604. As depicted, through-holes 604 comprise a curved path that curves around multiple different axes of curvature. Referring to the perspective shown in FIG. 7, where air flows in a direction extending from a front surface 610 to a back surface 612 of body 602, each through-hole 604 comprises both upward and side-to-side curvature, and thus curves around axes of curvature extending in both width and thickness directions. In addition to helping to ensure that all portions of an acoustic signal will impinge an interior wall of a through-hole 604, such a configuration also may help to create a spiral airflow pattern in a same direction as fan rotation. This may provide for a smoother airflow transition between acoustic attenuator 600 and a fan, and thereby may help to decrease airflow impedance. In some examples, a shape of the through-holes 604 may be tuned to reduce acoustic signals in a range of 4 kHz to 9 kHz and/or other suitable frequency ranges. Further, in some examples, a surface on the interior wall of through-hole 604 may comprise a coating of a sound attenuating material, which may further attenuate an acoustic signal.

FIG. 8 shows another example acoustic attenuator 800 comprising an array of through-holes, only one of which is schematically shown for clarity. Acoustic attenuator 800 is an example of acoustic attenuator 108. Acoustic attenuator 800 comprises a body 802, and a plurality of airflow channels comprising an array of through-holes extending through body 802. Instead of having a curved shape such as that depicted in FIG. 7, through-hole 804 comprises a spiral inner wall 806 that is similar to an extruded fan blade shape extending substantially the length of through-hole 804. In the depicted example, spiral inner wall 806 comprises four cross-sectional surfaces that spiral through a length of through-hole 804 such that a line of sight between a first end of through-hole 804 and a second end of through-hole 804 is blocked. In this configuration, acoustic signals entering through-hole 804 impinge the spiral inner wall 806, thereby attenuating the acoustic signals. In other examples, any other suitable number and arrangement of spiral inner walls may be used. Likewise, while the depicted through-hole comprises a round cross-sectional configuration, any other suitable cross-sectional shape may be used, including polygonal ones such as those listed above with regard to FIGS. 6-7. In some examples, as described above, the spiral inner wall may be coated with an acoustically attenuating material, or comprise an acoustically attenuating surface treatment.

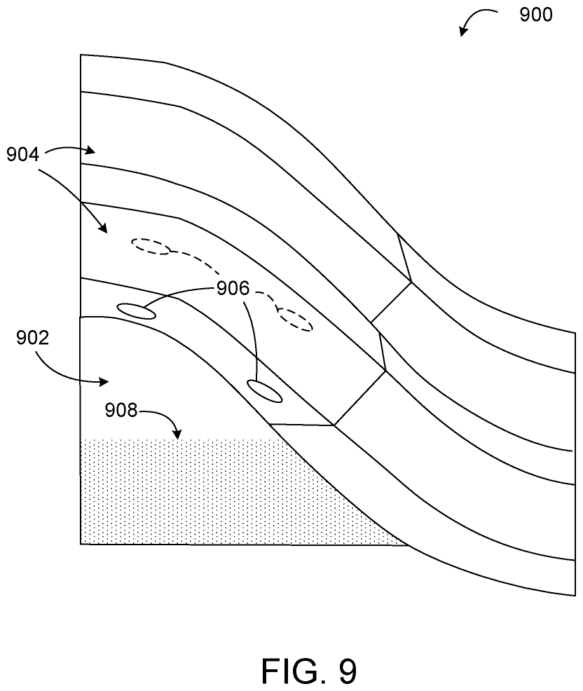

In some examples, an acoustic attenuator may comprise an absorbing chamber contained within the body of the attenuator. FIG. 9 schematically shows a portion of such an acoustic attenuator at 900. Acoustic attenuator 900 comprises a plurality of through-holes having a curved configuration, similar to acoustic attenuator 600. However, acoustic attenuator 900 further comprises an absorbing chamber, illustrated schematically at 902, positioned adjacent to one or more through-holes 904 of the acoustic attenuator 900. Through-holes 904 include openings 906 that connect through-holes 904, and that also connect to absorbing chamber 902. Openings 906 allow a portion of acoustic signals propagating through through-holes 904 to enter absorbing chamber 902. Similar to through-holes 904, absorbing chamber 902 may include a surface coating or treatment configured to absorb sound waves. Further, in some examples, absorbing chamber 902 may be at least partially filled with a sound-absorbing material 908 to further attenuate noise from fans.

Another example provides a computing storage system comprising an enclosure, a plurality of magnetic data storage devices positioned within the enclosure, one or more fans positioned to cool the magnetic data storage devices, and an acoustic attenuator located between the plurality of magnetic data storage devices and the one or more fans, the acoustic attenuator comprising a plurality of airflow channels each defined by one or more internal walls of the acoustic attenuator, wherein at least one of the plurality of airflow channels is configured to block a line of sight between the plurality of magnetic data storage devices and the one or more fans. In some such examples, the acoustic attenuator is tuned to reduce acoustic signals in a range of 4 KHz to 9 KHz. In some such examples, a sound-absorbing chamber positioned is alternatively or additionally located within the acoustic attenuator. In some such examples, a surface of the one or more internal walls alternatively or additionally comprises a coating of a sound attenuating material. In some such examples, the one or more internal walls alternatively or additionally comprises a wall having one or more of a curvature or an angular directional change that blocks the line of sight. In some such examples, at least one internal wall of the one or more internal walls alternatively or additionally comprises a curved trailing end. In some such examples, the plurality of airflow channels alternatively or additionally comprises an array of through-holes extending through a body of the acoustic attenuator. In some such examples, one or more of the through-holes alternatively or additionally comprises a spiral inner surface. In some such examples, one or more of the through-holes alternatively or additionally comprises a curved path that blocks the line of sight.

Another example provides an acoustic attenuator comprising a body, and plurality of airflow channels extending through the body, each airflow channel defined by one or more internal walls of the acoustic attenuator, wherein at least one of the plurality of airflow channels is configured to block a line of sight between a first end of the airflow channel and a second end of the airflow channel. In some such examples, the acoustic attenuator is tuned to reduce acoustic signals in a range of 4 KHz to 9 KHz. In some such examples, a surface of the one or more internal walls alternatively or additionally comprises a coating of a sound attenuating material. In some such examples, at least one internal wall of the one or more internal walls comprises a curved trailing end. In some such examples, the one or more internal walls alternatively or additionally comprises a wall having one or more of a curvature or an angular directional change that blocks the line of sight. In some such examples, the plurality of airflow channels alternatively or additionally comprise an array of through-holes extending through the body of the acoustic attenuator.

Another example provides a computing storage system comprising an enclosure, a plurality of magnetic data storage devices positioned within the enclosure, one or more fans contained within the enclosure and positioned to cool the HDDs, and an acoustic attenuator located between the plurality of magnetic data storage devices and the one or more fans, the acoustic attenuator comprising a plurality of airflow channels comprising an array of through-holes extending through a body of the acoustic attenuator, and wherein at least one of the through-holes comprises a curved surface that blocks a line of sight between a first end of the airflow channel and a second end of the airflow channel. In some such examples, the acoustic attenuator is tuned to reduce acoustic signals in a range of 4 KHz to 9 KHz. In some such examples, the attenuator alternatively or additionally further comprises an absorbing chamber positioned within the body of the acoustic attenuator. In some such examples, one or more of the through-holes alternatively or additionally comprises a spiral inner surface. In some such examples, one or more of the through-holes comprises a curved path that blocks the line of sight.

It will be understood that the configurations and/or approaches described herein presented for the purpose of example, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A computing storage system comprising:
an enclosure;
a plurality of magnetic data storage devices positioned within the enclosure;
one or more fans positioned to cool the magnetic data storage devices; and
an acoustic attenuator located between the plurality of magnetic data storage devices and the one or more fans, the acoustic attenuator comprising a plurality of airflow channels each defined by one or more internal walls of the acoustic attenuator, wherein at least one of the plurality of airflow channels is configured to block a line of sight between the plurality of magnetic data storage devices and the one or more fans.

2. The system of claim 1, wherein the acoustic attenuator is tuned to reduce acoustic signals in a range of 4 KHz to 9 KHz.

3. The system of claim 1, further comprising a sound-absorbing chamber positioned within the acoustic attenuator.

4. The system of claim 1, wherein a surface of the one or more internal walls comprises a coating of a sound attenuating material.

5. The system of claim 1, wherein the one or more internal walls comprise a wall having one or more of a curvature or an angular directional change that blocks the line of sight.

6. The system of claim 1, wherein at least one internal wall of the one or more internal walls comprises a curved trailing end.

7. The system of claim 1, wherein the plurality of airflow channels comprise an array of through-holes extending through a body of the acoustic attenuator.

8. The system of claim 7, wherein one or more of the through-holes comprises a spiral inner surface.

9. The system of claim 7, wherein one or more of the through-holes comprises a curved path that blocks the line of sight.

10. An acoustic attenuator comprising:
a body; and
a plurality of airflow channels extending through the body, each airflow channel defined by one or more internal walls of the acoustic attenuator, wherein at least one of the plurality of airflow channels is configured to block a line of sight between a first end of the airflow channel and a second end of the airflow channel.

11. The attenuator of claim 10, wherein the acoustic attenuator is tuned to reduce acoustic signals in a range of 4 KHz to 9 KHz.

12. The attenuator of claim 10, wherein a surface of the one or more internal walls comprises a coating of a sound attenuating material.

13. The attenuator of claim 10, wherein at least one internal wall of the one or more internal walls comprises a curved trailing end.

14. The attenuator of claim 10, wherein the one or more internal walls comprises a wall having one or more of a curvature or an angular directional change that blocks the line of sight.

15. The attenuator of claim 10, wherein the plurality of airflow channels comprise an array of through-holes extending through the body of the acoustic attenuator.

16. A computing storage system comprising:
an enclosure;
a plurality of magnetic data storage devices positioned within the enclosure;
one or more fans contained within the enclosure and positioned to cool the HDDs; and
an acoustic attenuator located between the plurality of magnetic data storage devices and the one or more fans, the acoustic attenuator comprising a plurality of airflow channels comprising an array of through-holes extending through a body of the acoustic attenuator, and wherein at least one of the through-holes comprises a curved surface that blocks a line of sight between a first end of the airflow channel and a second end of the airflow channel.

17. The attenuator of claim 16, wherein the acoustic attenuator is tuned to reduce acoustic signals in a range of 4 KHz to 9 KHz.

18. The attenuator of claim 16, further comprising an absorbing chamber positioned within the body of the acoustic attenuator.

19. The attenuator of claim 16, wherein one or more of the through-holes comprises a spiral inner surface.

20. The attenuator of claim 16, wherein one or more of the through-holes comprises a curved path that blocks the line of sight.
